(19) United States
(12) Patent Application Publication
(10) Pub. No.: US 2008/0061773 A1
(43) Pub. Date: Mar. 13, 2008

(54) Method of evaluating a magnetoresistance effect read head

(75) Inventors: Mitsuru Otagiri, Kawasaki (JP); Masato Matsubara, Kawasaki (JP)

Correspondence Address: GREER, BURNS & CRAIN, 300 S WACKER DR, 25TH FLOOR, CHICAGO, IL, 60606, US

(73) Assignee: FUJITSU LIMITED

(21) Appl. No.: 11/703,516

(22) Filed: Feb. 7, 2007

(30) Foreign Application Priority Data
Sep. 7, 2006 (JP) 2006-242411

(51) Int. Cl. G01R 33/12

(52) U.S. Cl. 324/210

(57) ABSTRACT

A method of evaluating can evaluate the bias magnetic field strength of hard films that construct a magnetoresistance effect read head, the magnetic coercivity of the hard films, and variations in the magnetic domain of shield films from measurement results for the resistance-parallel magnetic field strength characteristics. A magnetizing magnetic field is applied in a direction parallel to the air bearing surface of a magnetoresistance effect read head equipped with hard films to magnetize the hard films in a direction of a horizontal bias magnetic field applied to a free layer of the read element. After this, the resistance of the read element is detected and the resistance-parallel magnetic field strength characteristics of the read head are measured while applying a test magnetic field with increasing and decreasing intensity in a direction parallel to the horizontal bias magnetic field. The bias magnetic field strength of the hard films is evaluated from peaks appearing in the resistance-parallel magnetic field strength characteristics.

### BACKGROUND OF THE INVENTION

1. Field of the Invention

The present invention relates to a method of evaluating a magnetoresistance effect read head, and in more detail to a method of evaluating a magnetoresistance effect read head that applies a test magnetic field to a magnetoresistance effect read head and then evaluates the operation of the horizontal bias magnetic field of hard films provided in the read head.

2. Background of the Invention

Various types of read elements such as MR (Magnetoresistance), spin-valve GMR (Giant Magnetoresistance), TuMR (Tunneling Magnetoresistance), and CPP-GMR (Current Perpendicular Plane-GMR) read elements are used in magnetoresistance effect read heads that detect magnetically recorded information. Such read elements are provided with a free layer whose magnetization direction is changed by an external magnetic field and a pinned layer whose magnetization direction is fixed.

FIG. 10 shows the construction of a magnetoresistance effect read head (hereinafter simply “MR head”) and the positional relationship between the magnetoresistance effect read head 20 and a medium 40 during reproduction of magnetically recorded information on a medium.

The MR head 20 is equipped with a magnetoresistance effect element (MR element) 10, hard films 12a, 12b provided on either side of the MR element 10, and shield films 14a, 14b provided on both sides of the MR element 10 and the hard films 12a, 12b in the thickness direction (i.e., a direction perpendicular to the direction in which the MR element 10 and the hard films 12a, 12b) are aligned.

The hard films 12a, 12b are used to apply a horizontal bias magnetic field to the free layer of the MR element and are formed of ferromagnetic films. In the example shown in FIG. 10, the hard films 12a, 12b are magnetized so that the magnetization direction of the free layer is the negative direction along the x axis.

The shield films 14a, 14b shield the magnetically recorded information on adjacent tracks so that the magnetically recorded information directly below the MR element 10 can be sensed with high resolution. The shield films 14a, 14b are formed of soft magnetic films and are normally rectangular in planar form.

When the magnetic head moves over the medium 40, the end surfaces of the MR element 10, the hard films 12a, 12b, and the shield films 14a, 14b face the surface of the medium 40 and the direction of the horizontal bias magnetic field applied by the hard films 12a, 12b and the length direction of the end surfaces of the shield films 14a, 14b are aligned with the track width direction (i.e., the x-axis).

In addition to an MR read head, a magnetic head is equipped with a write head that magnetically records information on a medium. Since the content of the present invention relates to the evaluation of the characteristics of a read head, only the construction of the MR head 20 is shown in FIG. 10.

During the manufacturing of a magnetic head, to test the characteristics of the MR head, conventionally a magnetic field is applied in a direction perpendicular to the air bearing surface of the magnetic head (i.e., in the y-axis) and the change in resistance relative to the intensity of the applied magnetic field is measured. In other words, the R (resistance)-H (perpendicular magnetic field strength) characteristics are tested (see, for example, Patent Documents 1 to 4). In such tests, the direction of the magnetic field applied to the MR head is set as the same direction as a magnetic field that acts upon the MR head from a medium (i.e., a direction perpendicular to the air bearing surface of the magnetic head). This means that a state where the magnetic head is operating over a “virtual medium” is produced, and the characteristics of the MR head are evaluated by testing the output value and instability in output of the MR head in such state.

FIG. 11 shows the measurement results obtained by an R-H characteristics test. Here, the ratio of the change in resistance (ΔR) with respect to the change in magnetic field strength (ΔH) is proportional to the output, and the characteristics of the MR head are evaluated from such test results.

### Patent Document 1

Japanese Laid-Open Patent Publication No. H10-269537

### Patent Document 2

Japanese Laid-Open Patent Publication No. H11-086239

### Patent Document 3

Japanese Laid-Open Patent Publication No. 2000-099932

### Patent Document 4

Japanese Laid-Open Patent Publication No. 2002-216326

### SUMMARY OF THE INVENTION

The method of evaluating an MR head described above perpendicularly applies a test magnetic field to the air bearing surface of a magnetic head and evaluates whether the MR head has the required output characteristics. This method is used when sorting out non-defective MR heads during the manufacturing process.

Instability or fluctuations in the output of an MR head are thought to be caused by the characteristics of the free layer and pinned layer that construct the MR element, the hard films that apply the horizontal bias magnetic field to the free layer, and the shield films used for magnetic shielding. However, with the conventional method of evaluating that applies a perpendicular magnetic field to an MR head, it is almost impossible to evaluate the characteristics of the hard films, for example, and to judge whether the hard films are defective. It is fair to say that a process where an external magnetic field is applied to an MR head and the characteristics of the hard films are evaluated from the output value of the MR element has not been conventionally carried out.

The present invention was conceived to solve the problem of it being difficult to accurately evaluate the characteristics of construction elements, such as the hard films and shield films, which construct an MR head with a conventional method of evaluating an MR head such as those described above. It is an object of the present invention to provide a method of evaluating a magnetoresistance effect read head that can easily and reliably evaluate the characteristics of hard films and the like that construct the MR head.

To achieve the stated object, a method of evaluating a magnetoresistance effect read head according to the present invention includes: a step of applying a magnetizing magnetic field to a magnetoresistance effect read head equipped with hard films in the same direction as the air bearing surface to magnetize the hard films in a direction of a horizontal bias magnetic field to be applied to a free layer of a read element; and a step of detecting the resistance of the read element and measuring resistance-parallel magnetic field strength characteristics (“R-H characteristics”) of the read head while applying a test magnetic field with increasing and decreasing intensity in a direction parallel to the horizontal bias magnetic field, and evaluating the horizontal bias magnetic field strength of the hard films from peaks appearing in the resistance-parallel magnetic field strength characteristics.

The R-H characteristics are measured by applying a test magnetic field parallel to the direction of a horizontal bias magnetic field and increasing and decreasing the applied magnetic field strength so as to sweep a magnetic field in the direction of the horizontal bias magnetic field (e.g., the positive direction) and in a reverse direction to the direction of the horizontal bias magnetic field (e.g., the negative direction). To evaluate the horizontal bias magnetic field strength of the hard films, a test magnetic field is applied until the intensity exceeds the effective horizontal bias magnetic field that acts on the free layer.

Another method of evaluating a magnetoresistance effect read head includes: a step of applying a magnetizing magnetic field to a magnetoresistance effect read head equipped with hard films to magnetize the hard films in a direction of a horizontal bias magnetic field to be applied to a free layer of a read element; and a step of applying a test magnetic field with increasing and decreasing intensity parallel to the horizontal bias magnetic field while raising a maximum applied magnetic field strength, detecting the resistance of the read element and measuring resistance-parallel magnetic field strength characteristics of the read head, and evaluating the magnetic coercivity of the hard films from an applied magnetic field strength at a position where a waveform is reversed in the resistance-parallel magnetic field strength characteristics.

When evaluating the magnetic coercivity of the hard films, after a test magnetic field has been applied on both the positive and negative side in the R-H characteristics, the intensity of the test magnetic field is increased until peaks appear due to a reversal in the magnetization direction of the free layer on both the positive and the negative sides.

Another method of evaluating a magnetoresistance effect read head according to the present invention includes: a step of applying a magnetizing magnetic field to a magnetoresistance effect read head equipped with hard films to magnetize the hard films in a direction of a horizontal bias magnetic field to be applied to a free layer of a read element; and a step of detecting the resistance of the read element and measuring resistance-parallel magnetic field strength characteristics of the read head while applying a test magnetic field with increasing and decreasing intensity in a direction parallel to the horizontal bias magnetic field, and evaluating variations in a magnetic domain of shield films provided in the read element from peaks appearing in the resistance-parallel magnetic field characteristics.

An external magnetic field that causes variations in the magnetic domain of the shield films is weak compared to an external magnetic field that reverses the magnetization direction of the free layer. Accordingly, by applying a test magnetic field used when evaluating the horizontal bias magnetic field strength, it is possible to simultaneously detect variations in the magnetic domain of the shield films.

The method of evaluating a magnetoresistance effect read head according to the present invention magnetizes the hard films and applies a test magnetic field in parallel to the horizontal bias magnetic field to detect the horizontal bias magnetic field strength produced by the hard films, the magnetic coercivity of the hard films, and variations in the magnetic domain of the shield films. By doing so, it is possible to reliably obtain the characteristics of the hard films and the like that were completely unobtainable with a conventional method of evaluating that applies a test magnetic field perpendicularly to the horizontal bias magnetic field. Since it is possible to obtain the effective magnetic field strength that acts on the free layer and the like as numerical data, magnetic heads can be evaluated more precisely, which is effective such as when designing a magnetic head with higher accuracy.

### BRIEF DESCRIPTION OF THE DRAWINGS

The aforementioned and other objects and advantages of the present invention will become apparent to those skilled in the art upon reading and understanding the following detailed description with reference to the accompanying drawings.

In the drawings:

FIG. 1 is a diagram showing the construction of a read head and the direction of a magnetic field applied by the method according to the present invention;

FIG. 2 shows an example of the R-H characteristics obtained by the method according to the present invention;

FIG. 3 is a diagram useful in explaining an R-H characteristics curve and observation results of the magnetization direction of the shield films;

FIGS. 4A and 4B are examples of the R-H characteristics obtained when the hard films have been magnetized in a positive direction;

FIGS. 5A and 5B are examples of the R-H characteristics obtained when the hard films have been magnetized in a negative direction;

FIG. 6 is a diagram showing the R-H characteristics and the magnetization direction of the hard films when the applied magnetic field strength is increased to a level where the magnetization direction of the hard films is reversed;

FIG. 7 is a diagram showing the shield width and shield height of the shield films;

FIG. 8 is a plan view schematically showing the construction of a magnetic disk apparatus;

FIG. 9 is a perspective view of a head slider installed in a magnetic disk apparatus;

FIG. 10 is a diagram showing the construction of a read head of a magnetic head and the positional relationship between the read head and the medium; and

FIG. 11 is an R-H characteristics curve obtained by a conventional method of evaluating.

### DESCRIPTION OF THE PREFERRED EMBODIMENTS

A method of evaluating a magnetoresistance effect read head (or simply “MR head”) according to the present invention is characterized by applying a test magnetic field in parallel to the air bearing surface of a magnetic head and evaluating the magnetic head by detecting the output of a magnetoresistance effect element (or simply “MR element”).

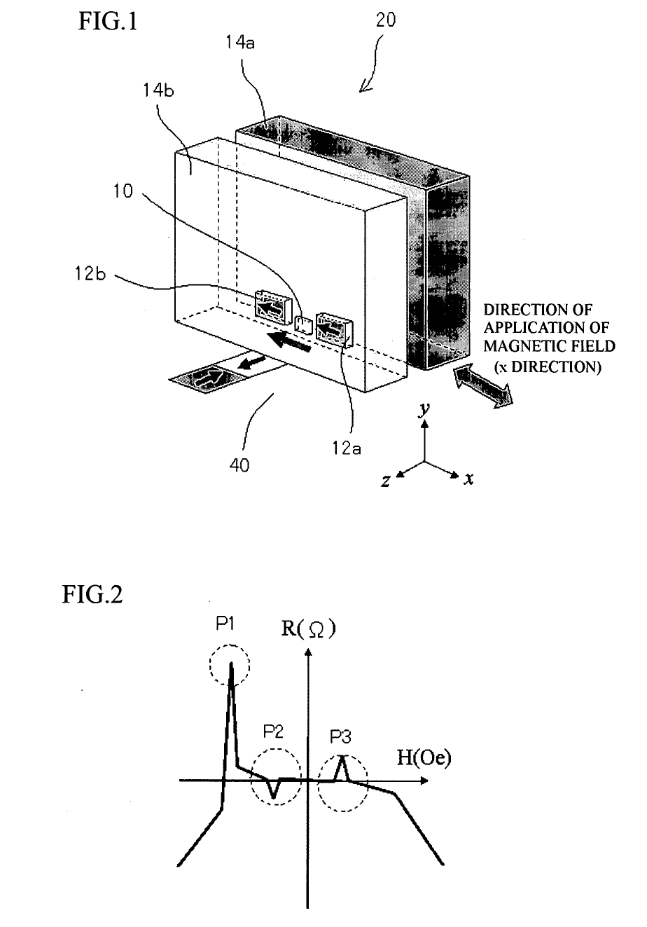

FIG. 1 shows the construction of an MR head 20, the positional relationship between a medium 40 and the MR head 20, and the direction of the magnetic field applied to the MR head 20. The construction of the MR head 20 is the same as the construction of the MR head 20 shown in FIG. 10 and therefore parts that are the same have been assigned the same reference numerals and description thereof is omitted.

In the present embodiment, the test magnetic field applied to the MR head 20 is applied in a direction that is parallel to the air bearing surface of the magnetic head and, more specifically, in a direction (the x-axis) that is parallel to the horizontal bias magnetic field produced by the hard films 12a, 12b. This direction of application of the test magnetic field is rotated by 90° (on the x-y plane) with respect to the direction of the magnetic field applied in a conventional method of evaluating an MR head. To change the direction of the test magnetic field applied to the magnetic head by 90° compared to the conventional method, it is possible to rotate the direction of the conventional test magnetic field by 90° or to rotate the magnetic head being tested by 90°. Accordingly, it is easy to make the direction of the magnetic field applied to the MR head 20 parallel to the air bearing surface of the magnetic head using a conventional testing apparatus.

When the test magnetic field is applied to the magnetic head, the magnetization directions of the free layer, the pinned layer, the hard films, and the shield films vary according to the direction of the applied magnetic field. Accordingly, to reliably evaluate the characteristics of such parts, it is necessary to adjust the direction of the applied test magnetic field and the intensity of the test magnetic field.

The present inventor measured many samples while changing the intensity of the test magnetic field applied to the MR head 20 and the direction of the test magnetic field and found that when the resistance-parallel magnetic field characteristics (R-H characteristics) were measured according to the following conditions, a characteristic pattern appeared in the R-H characteristics profiles produced by all of the tests.

(1) Applied magnetic field strength: ±1500 to ±3000 (Oe)
(2) Direction of applied magnetic field: parallel to the magnetization direction of the hard films

FIG. 2 shows the obtained R-H characteristics. In FIG. 2, the horizontal axis represents the magnetic field strength H (Oe) and the vertical axis represents resistance (Ω). As shown in FIG. 2, if the R-H characteristics are measured using the Conditions (1) and (2) above, three peaks P1, P2, and P3 appear for every sample.

Peak P1 appears in a range of −1500 (Oe) to −800 (Oe), Peak P2 in a range of −500 (Oe) to −200 (Oe), and Peak P3 in a range of +200 (Oe) to +500 (Oe). Depending on the sample, there were cases where Peak P1 appears as a plus peak and as a negative peak. Peaks P2 and P3 appear on the positive and negative sides for the magnetic field strength, and in samples of the same specification, the absolute values of the peak values (R) and the absolute values of the magnetic field strength (H) where the peaks occur were substantially equal.

### Regarding Peaks P2, P3

The reason why such peaks occur in the R-H characteristic curves was confirmed as follows. First, a sample where Peak P2 appears at −450 (Oe) and Peak P3 appears at +450 (Oe) in the R-H characteristics was used. While changing the applied magnetic field strength, the output (resistance) of the MR head was detected and changes in the magnetization direction of the shield films 14a, 14b were simultaneously investigated using a magnetic domain observation microscope that uses the Kerr effect. The measurement procedure was as follows.

### Step 1: Magnetize at a magnetic field strength of 5k (Oe) in the positive direction.

Step 2: Next, the applied magnetic field strength is restored to 0 (Oe) and then gradually increased in the negative direction. After Peak 1 has been detected, the applied magnetic field strength is restored to 0 (Oe) and then gradually increased in the positive direction. After this, the applied magnetic field strength is again restored to 0 (Oe).

In Step 1, the reason the sample is magnetized at 5k (Oe) in the positive direction is to magnetize the hard films 12a, 12b in the positive direction (the direction of the arrows) as shown in FIG. 1 so that a horizontal bias magnetic field acts on the MR element 10.

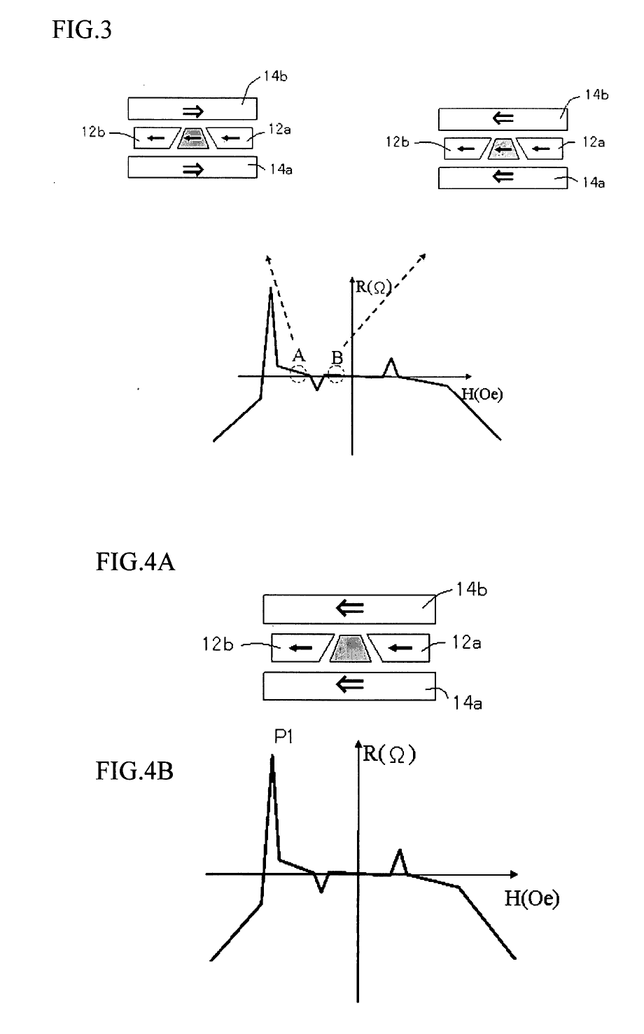

In Step 2, the operation that increases (sweeps) the magnetic field strength in the negative direction after restoring the magnetic field strength to 0 (Oe) corresponds to an operation that gradually applies a magnetic field with a reverse direction to the magnetization direction shown in FIG. 1. This corresponds to when the magnetic field strength (H) gradually increases in the negative direction from 0 (Oe) in the R-H characteristics shown in FIG. 3C.

FIG. 3 shows a state where the magnetization directions of the hard films 12a, 12b and the shield films 14a, 14b are observed using a magnetic domain observation microscope while the magnetic field strength is being increased from 0 (Oe) in the negative direction in Step 2 described above. Each arrow shows a magnetization direction.

As shown in FIG. 3, it was observed that although the magnetization direction of the shield films 14a, 14b is the positive direction (the same direction as the magnetizing direction in Step 1) when the applied magnetic field strength (H) is in a range of −400 (Oe) to 0 (Oe) (i.e., the region B in the R-H characteristics), the magnetization direction of the shield films 14a, 14b becomes the negative direction (the opposite direction to the magnetizing direction in Step 1) when the applied magnetic field strength (H) is −1000 (Oe) to −450 (Oe) (i.e., the region A in the R-H characteristics).

It is believed that the peak produced near −450 (Oe) in the R-H characteristics is due to the reversing of the magnetization direction of the shield films 14a, 14b at around −450 (Oe) after the shield films 14a, 14b have been magnetized in the positive direction in Step 1 (i.e., the peak is due to the variation in magnetic domain caused by such reversing).

Next, after the applied magnetic field was restored to 0 (Oe) from a value in the negative direction, the external magnetic field was increased (swept) in the positive direction, a peak was seen in the output of the MR head at around +450 (Oe), and it was observed that the magnetization direction of the shield films 14a, 14b became reversed at or near such position. The peak produced near the +450 (Oe) position in the R-H characteristics is also due to the reversing of the magnetization direction of the shield films 14a, 14b (i.e., the peak is due to the variation in magnetic domain).

From the above, it was understood that the peaks P2, P3 obtained by measuring the R-H characteristics are caused by the large variations in the magnetic domain of the shield films 14a, 14b due to the action of the test magnetic field.

### Regarding Peak P1

A horizontal bias magnetic field is constantly applied on the free layer that composes the MR element from the hard films 12a, 12b. When the MR head has been magnetized in the positive direction, that is, when the hard films 12a, 12b have been magnetized with the magnetization direction shown in FIG. 1 (the direction of the arrows), even if a magnetic field is applied to the MR element 10 in the negative direction (a reverse direction to the direction of the horizontal bias magnetic field), so long as the external magnetic field in the negative direction is weaker than the horizontal bias magnetic field, the free layer will remain magnetized in the positive direction.

However, it is believed that as the intensity of the external magnetic field is gradually increased in the negative direction and becomes equal to the horizontal bias magnetic field produced by the hard films 12a, 12b, the magnetic field acting on the free layer becomes effectively zero. If the intensity of the external magnetic field further increases so as to exceed the intensity of the horizontal bias magnetic field, the magnetization direction of the free layer is reversed.

When the magnetization direction of the free layer is reversed, the magnetization direction will definitely pass a state where the direction is parallel to or antiparallel to the magnetization direction of the pinned layer, with the resistance value peaking at such time.

In a curve produced by measuring the R-H characteristics, peak P1 will definitely appear as a large positive or negative peak at a position that is opposite to the direction in which the hard films 12a, 12b were magnetized. It is supposed that this is caused by the magnetization direction of the free layer becoming reversed due to the action of the external magnetic field applied to the MR head.

To confirm this supposition, the R-H characteristics were measured both for the case where the hard films 12a, 12b were magnetized in the positive direction (the direction of the arrows in FIG. 1) and the case where the hard films 12a, 12b were magnetized in the negative direction (the opposite direction to that shown in FIG. 1).

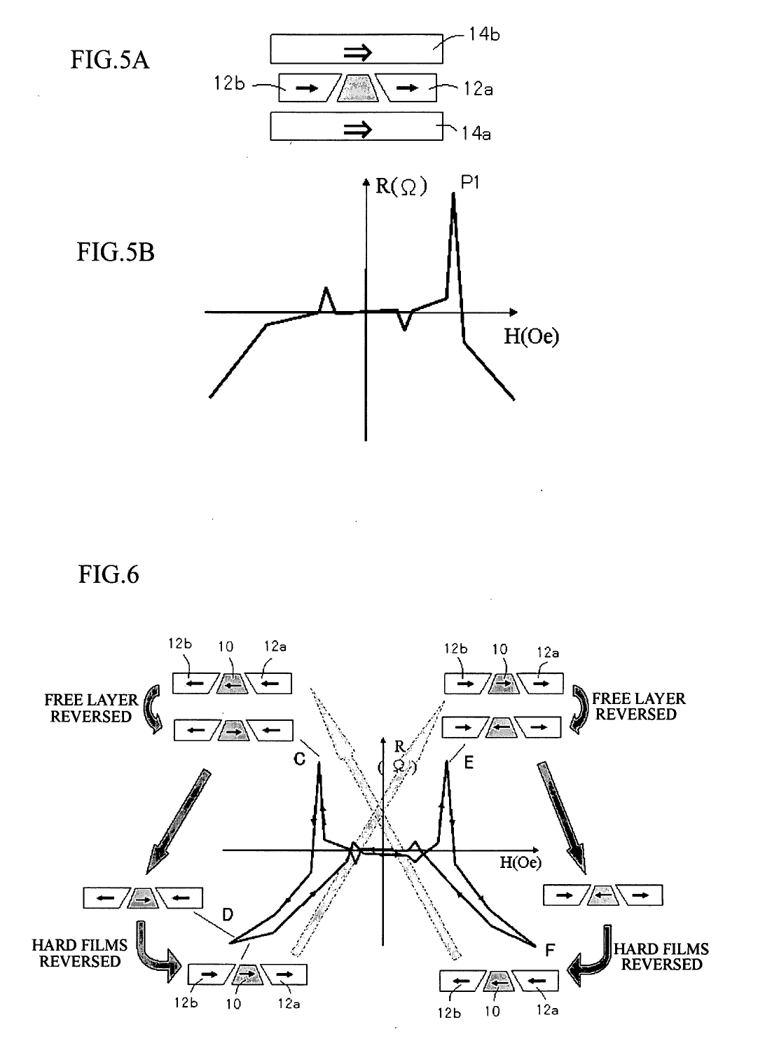

FIGS. 4A, 4B and 5A, 5B show the measurement results. FIGS. 4A and 4B show that a large peak appears at around −900 (Oe) when the hard films 12a, 12b have been magnetized in the positive direction and the intensity of the external magnetic field is increased in the negative direction and that no large peak appears when the external magnetic field has been restored to 0 (Oe) and the intensity is thereafter increased in the positive direction. FIGS. 5A and 5B show that a large peak appears at around +900 (Oe) when the hard films 12a, 12b have been magnetized in the negative direction and the intensity of the external magnetic field is increased in the positive direction and that no large peak appears when the external magnetic field has been restored to 0 (Oe) and the intensity is thereafter increased in the negative direction. It can also be understood that when the hard films 12a, 12b are magnetized in the positive and negative directions, the obtained R-H characteristics are symmetrical about the R axis (the vertical axis).

In these experiment results, peak P1 in the R-H characteristics curve is a peak due to the effect of the horizontal bias magnetic field produced by the hard films 12a, 12b and shows the point where the horizontal bias magnetic field applied to the free layer by the hard films 12a, 12b matches the external magnetic field (a magnetic field that is parallel to the air bearing surface of the magnetic head). Therefore, the peak position shows the effective horizontal bias magnetic field applied to the free layer by the hard films 12a, 12b.

### Reversal of the Magnetization Direction of the Hard Films

Peak P1 that appears in the R-H characteristics corresponds to a state where the horizontal bias magnetic field applied by the hard films 12a, 12b matches the external magnetic field, but when the intensity of the test magnetic field applied from outside the magnetic head is increased further, it is thought that the magnetization direction of the hard films 12a, 12b themselves will also be reversed.

When the magnetic field applied to the MR head was increased to ±3k (Oe) during the measurement of the R-H characteristics, Peak P1, which appeared on only one of the negative side and the positive side during the measuring described above, appears on both the negative side and the positive side.

FIG. 6 shows the resistance-parallel magnetic field strength characteristics (R-H characteristics) obtained when sweeping (increasing and decreasing) the applied magnetic field in a range of ±3k (Oe) and the magnetization directions of the free layer and the hard films 12a, 12b of the MR element 10 when doing so.

After the MR head has been magnetized in the positive direction (the magnetization direction shown in FIG. 1), the magnetic field is restored to 0 (Oe) and as the intensity of the magnetic field applied in the negative direction is increased, a peak due to variations in the magnetic domain of the shield films 14a, 14b is detected first. After this, peak P1 (point C) appears where the magnetization direction of the free layer of the MR element 10 is reversed with respect to the direction of the horizontal bias magnetic field produced by the hard films 12a, 12b. When the magnetic field is further increased in the negative direction, the magnetization direction of the hard films 12a, 12b themselves becomes reversed (point D).

After the magnetization direction of the hard films 12a, 12b has been reversed, the magnetic field is restored to 0 (Oe). As the intensity of the magnetic field is increased in the positive direction, variations in the magnetic domain of the shield films 14a, 14b are detected first, and then a large peak (point E) appears due to the magnetization direction of the free layer becoming reversed with respect to the direction of the horizontal bias magnetic field produced by the hard films 12a, 12b. When the magnetic field is further increased in the positive direction, the magnetization direction of the hard films 12a, 12b themselves becomes reversed (point F).

After the magnetization direction of the hard films 12a, 12b has been reversed, the magnetic field is restored to 0 (Oe). As the magnetic field is applied in the negative direction, the state at point C will be reached again. In this way, the R-H characteristics trace a loop-shaped characteristics curve like that shown in FIG. 6.

In this way, when the test magnetic field applied to the MR head is increased to a sufficient intensity to reverse the magnetization direction of the hard films 12a, 12b, large peaks that are caused by the magnetization direction of the free layer reversing due to the action of the external magnetic field appear at symmetrical positions in the R-H characteristics on both the positive and negative sides. This means that in addition to information about the effective horizontal bias magnetic field produced by the hard films 12a, 12b, it is possible to obtain information about the magnetic coercivity of the hard films 12a, 12b.

Note that the test magnetic field affects the magnetization direction of the hard films 12a, 12b as described above and in the same way also affects the pinned layer that is formed on the MR element and whose magnetization is fixed. If the intensity of the test magnetic field is increased until approximately a value that exceeds the horizontal bias magnetic field that acts on the free layer, the magnetization direction of the pinned layer also becomes tilted (i.e., rotated) from the initial magnetization direction.

In the R-H characteristics curve shown in FIG. 2, it is believed that the resistance gradually falls after the magnetic field strength exceeds the peak P1 in the negative direction due to a gradual increase in the angle by which the magnetization direction of the pinned layer is tilted from the initial magnetization direction as the applied magnetic field increases. This results in variation in the angle between the magnetization direction of the pinned layer and the magnetization direction of the free layer. When the applied magnetic field increases in the positive direction, the resistance gradually falls for the same reason. In this way, it is believed that this method of measuring the R-H characteristics by applying a test magnetic field in parallel to the horizontal bias magnetic field also reflects the action of the pinned layer of the MR element.

### SPECIFIC EXAMPLE

The method of evaluating a magnetoresistance effect read head according to the present invention was used to test magnetic heads that were actually manufactured. When doing so, the R-H characteristics were measured, and (1) the effective horizontal bias magnetic field strength Hhb applied to the free layer of the MR element, (2) the magnetic field strength Hsh at which the magnetization direction of the shield films was reversed, and (3) the magnetic coercivity Hhc of the hard films were compared. The measurement results are shown in Table 1 below.

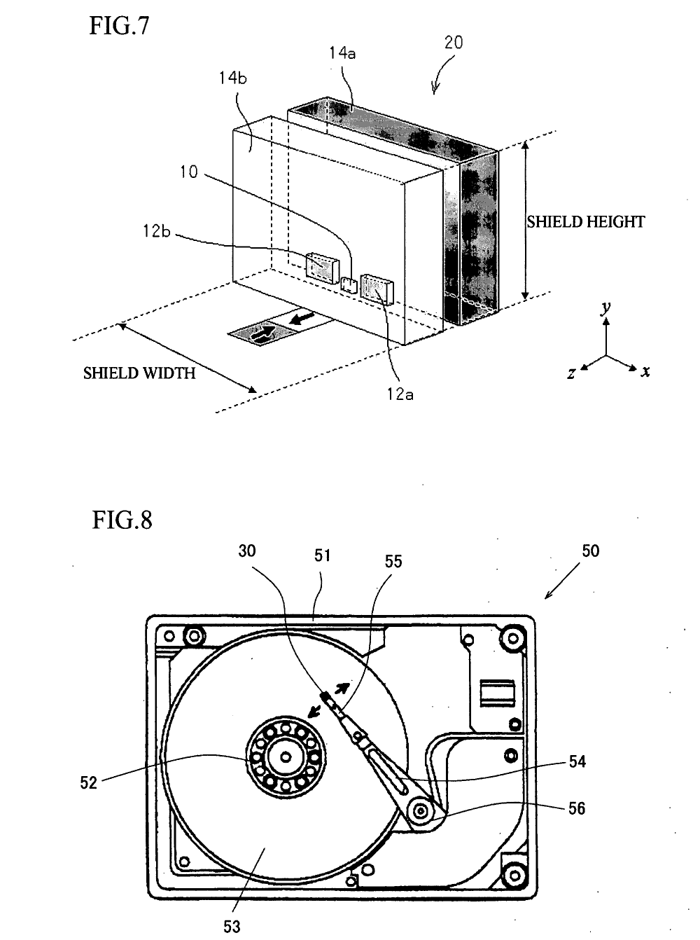

Note that five samples were measured. As shown in FIG. 7, the upper and lower shield films 14a, 14b disposed on both sides of the MR element 10 are both rectangular in planar form. The width and height of the shield films 14a, 14b are defined according to the orientation shown in FIG. 7.

TABLE 1

| | Shield Size | Specification of | | | | |
|---|---|---|---|---|---|---|
| | width (μm) × height | hard films | | Hhb | Hsh | Hhc |
| Sample | (μm) | tBr(Gμm) | Material | (Oe) | (Oe) | (Oe) |
| A | 90 × 25 | 167 | CoCrPt | 800 | 250 | — |
| B | 60 × 40 | 183 | CoCrPt | 950 | 450 | 3000 |
| C | 60 × 40 | 200 | CoCrPt | 1000 | 450 | 3000 |
| D | 60 × 40 | 217 | CoCrPt | 1050 | 450 | 3000 |
| E | 60 × 40 | 188 | CoPt | 930 | 450 | 3300 |

By comparing the measurement results for samples B, C, and D, it can be understood that Hhb increases as the product tBr of the thickness (μm) of the hard films 12a, 12b and the remanent magnetization (Gauss) increases. It is normally said that as hard films become thicker and tBr increases, the horizontal bias magnetic field applied to the free layer increases, and the characteristics become more stable. By using the method of evaluating according to the present invention, as shown in Table 1, it is possible to numerically confirm the intensity of the horizontal bias magnetic field produced by the hard films. This is extremely valuable since it allows the effective magnetic field strength produced by the hard films to be understood through testing.

The value Hsh differs only for sample A, whose shield size differs to all of the other samples. From this result, it was understood that when the shield size differs, the magnetic field strength produced due to changes in magnetization of the shield films also changes. It was also understood that the narrower the shield width, the larger the value of Hsh.

On the other hand, it is known that the magnetic coercivity of the hard films 12a, 12b depends on the material used. Regarding the measurement results for Hhc, although the value of Hhc was 3000 (Oe) for the samples B, C, and D that use CoCrPt, Hhc was 3300 (Oe) for the sample E that uses CoPt. In this way, it was confirmed that Hhc changes depending on the material used for the hard films 12a, 12b.

The measuring described above was carried out after a magnetic head that includes a read head and a write head has been formed. Since the method according to the present invention can be used even after a magnetic head has been formed, it is possible to use this method of evaluating the characteristics of a read head by applying a test magnetic field to individual magnetic heads after the magnetic heads have been fabricated on a ceramic wafer, for example.

Also, by using the method of evaluating a magnetoresistance effect read head according to the present invention, it is possible to obtain the characteristics of hard films and shield films as objective numerical data. This method can be effectively used when designing a highly reliable magnetic head with higher precision.

### Magnetic Disk Apparatus

FIG. 8 shows one example of a magnetic disk apparatus in which magnetic heads that have been evaluated using the method of evaluating described above are installed. Inside a casing 51 formed in the shape of a rectangular box, this magnetic disk apparatus 50 includes a plurality of magnetic recording disks 53 that are rotated by a spindle motor 52. Carriage arms 54 that are supported so as to be capable of swinging in parallel to the disk surfaces are disposed beside the magnetic recording disks 53. Head suspensions 55 are attached to the front ends of the carriage arms 54 so as to extend in the length direction of the carriage arms 54 and head sliders 30 are attached to the front ends of such head suspensions 54. Each head slider 30 is attached to a surface of a head suspension 55 that faces a disk surface.

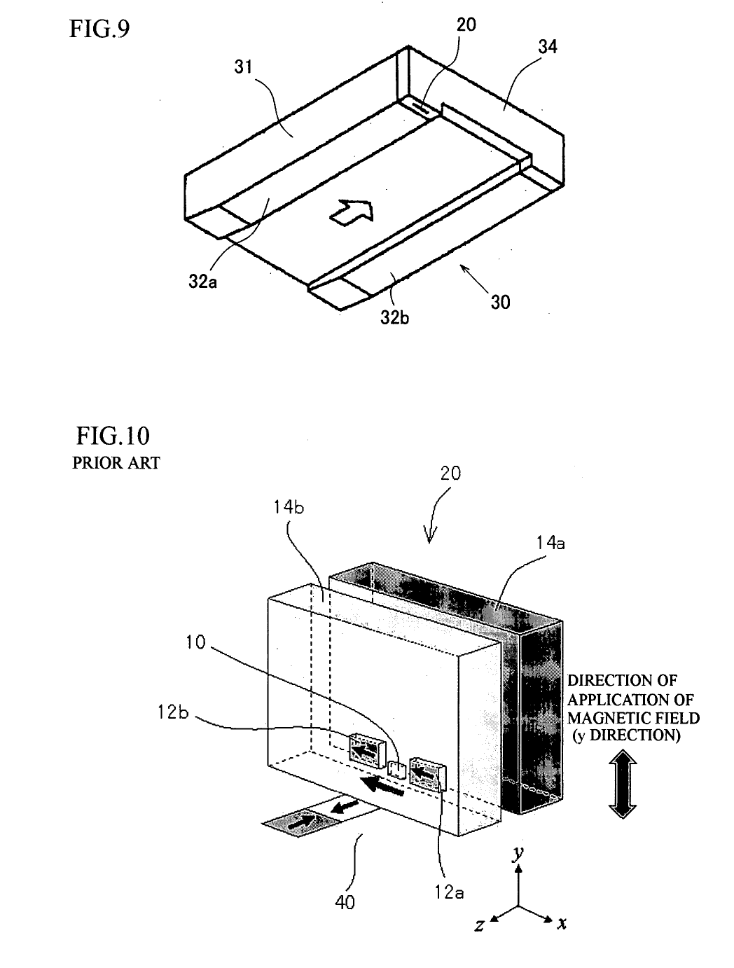

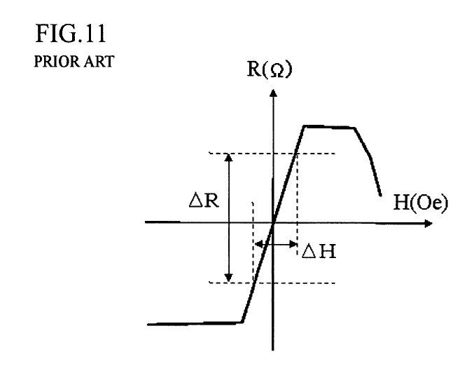

FIG. 9 is a perspective view of a head slider 30. Side rails 32a, 32b are provided along the side edges of a slider body 31 on the surface (ABS surface) of the head slider 30 that faces a magnetic disk so that the head slider 30 is lifted above the magnetic disk surface. A magnetic head 20 that has been evaluated according to the method of evaluating described earlier is disposed so as to face the magnetic disk on the front end side (the side where air flows out) of the head slider 30. The MR head 20 is covered with and protected by a protective film 34.

When the magnetic recording disks 53 are rotated by the spindle motor 52, the head slider 30 flies above a disk surface due to the flow of air generated by the rotation of the magnetic recording disks 53, a seek operation is carried out by the actuator 56, and a process where information is recorded and/or information is reproduced onto or from the magnetic recording disks 53 is carried out by the magnetic head 20.

What is claimed is:

1. A method of evaluating a magnetoresistance effect read head, comprising:
a step of applying a magnetizing magnetic field to a magnetoresistance effect read head equipped with hard films to magnetize the hard films in a direction of a horizontal bias magnetic field to be applied to a free layer of a read element; and
a step of detecting the resistance of the read element and measuring resistance-parallel magnetic field strength characteristics of the read head while applying a test magnetic field with increasing and decreasing intensity in a direction parallel to the horizontal bias magnetic field, and evaluating the horizontal bias magnetic field strength of the hard films from peaks appearing in the resistance-parallel magnetic field strength characteristics.

2. A method of evaluating a magnetoresistance effect read head, comprising:
a step of applying a magnetizing magnetic field to a magnetoresistance effect read head equipped with hard films to magnetize the hard films in a direction of a horizontal bias magnetic field to be applied to a free layer of a read element; and
a step of applying a test magnetic field with increasing and decreasing intensity parallel to the horizontal bias magnetic field while raising a maximum applied magnetic field strength, detecting the resistance of the read element and measuring resistance-parallel magnetic field strength characteristics of the read head, and evaluating the magnetic coercivity of the hard films from an applied magnetic field strength at a position where a waveform is reversed in the resistance-parallel magnetic field strength characteristics.

3. A method of evaluating a magnetoresistance effect read head, comprising:
a step of applying a magnetizing magnetic field to a magnetoresistance effect read head equipped with hard films to magnetize the hard films in a direction of a horizontal bias magnetic field to be applied to a free layer of a read element; and
a step of detecting the resistance of the read element and measuring resistance-parallel magnetic field strength characteristics of the read head while applying a test magnetic field with increasing and decreasing intensity in a direction parallel to the horizontal bias magnetic field, and evaluating variations in a magnetic domain of shield films provided in the read element from peaks appearing in the resistance-parallel magnetic field characteristics.
